(19) United States
(12) Patent Application Publication
(10) Pub. No.: US 2024/0290839 A1
(43) Pub. Date: Aug. 29, 2024

(54) METHOD FOR FORMING A LAYER STRUCTURE SURROUNDING AT LEAST ONE RECESS, AND DEVICE WITH A LAYER STRUCTURE

(71) Applicant: Robert Bosch GmbH, Stuttgart (DE)

(72) Inventors: Heribert Weber, Nuertingen (DE); Peter Schmollngruber, Aidlingen (DE)

(21) Appl. No.: 18/693,231

(22) PCT Filed: Feb. 14, 2023
(86) PCT No.: PCT/EP2023/053662

§ 371 Date: Mar. 19, 2024

(30) Foreign Application Priority Data
Feb. 22, 2022 (DE) 10 2022 201 813.3

(51) Int. Cl. H01L 29/06; H01L 21/02; H01L 21/306; H01L 21/3065

(52) U.S. Cl. CPC H01L 29/0684; H01L 21/02675; H01L 21/30604; H01L 21/3065

(57) ABSTRACT

A method for forming a layer structure surrounding at least one recess. The method includes: structuring a multitude of depressions in a first semiconductor layer of the later layer structure such that the depressions form at least one contiguous recess, including a plurality of depressions, in the first semiconductor layer, into which wall structures structured out of the first semiconductor layer by means of the depressions project; at least partially areally covering the at least one recess by forming at least one second semiconductor layer from the at least one identical material to the first semiconductor layer; and introducing a medium through at least one medium supply opening into the at least one recess, which medium chemically reacts with the projecting wall structures.

### FIELD

The present invention relates to a method for forming a layer structure surrounding at least one recess. The present invention also relates to devices with a layer structure.

### BACKGROUND INFORMATION

U.S. Pat. No. 10,578,505 B2 describes a process for forming a cavern, covered by a silicon membrane, in a monocrystalline silicon wafer. When performing the conventional process, a multitude of trenches is first etched into the silicon wafer such that a multitude of pillars is structured out of the silicon wafer. The trenches are subsequently closed by epitaxial deposition of a silicon layer. Thereafter, a high-temperature tempering step is performed in a hydrogen atmosphere at 1190° C. for 30 minutes, wherein, by rearranging the material of the columns previously structured out of the silicon wafer, the silicon layer is to be convertible into the desired silicon membrane, which spans a column-free cavern at the location of the earlier trenches.

### SUMMARY

The present invention creates a method for forming a layer structure surrounding at least one recess, a first device, and a second device.

The present invention enables the production of a layer structure surrounding at least one recess, wherein, even in a comparatively large-area formation of the at least one recess and with a relatively thin layer thickness of the second/third semiconductor layer at least partially areally covering the at least one recess, undesirable deflection or bulging of the second/third semiconductor layer is prevented. Even in a production of at least one component on a side of the second/third semiconductor layer that faces away from the first semiconductor layer, such as at least one conductive path and/or at least one resistance structure, at least remainders of the first/second wall structures can be used as support structures for supporting at least the second/third semiconductor layer so that, even then, an undesirable deflection or bulging of the second/third semiconductor layer of the layer structure is not/hardly to be expected.

In an advantageous embodiment of the method of the present invention, a product of the chemical reaction of the medium with the first wall structures is removed from the at least one first recess. The embodiment of the method of the present invention described here is therefore also suitable for the production of a layer structure, the at least one recess of which is “free” of residues of the product of the chemical reaction.

Advantageously, according to an example embodiment of the present invention, the first wall structures converted at least partially into the product of the chemical reaction due to the chemical reaction with the medium can be used as support structures for supporting at least the second semiconductor layer for at least one further process performed between the introduction of the medium and the removal of the product of the chemical reaction. In particular, the removal of the product of the chemical reaction can be delayed until all critical processes with respect to deflection or bulging of the second semiconductor layer are completed.

For example, the medium can be introduced into and/or held in the at least one first recess until the first wall structures projecting into the at least one first recess are fully converted into the product of the chemical reaction due to the chemical reaction of the medium with the first wall structures. Optionally, the chemical reaction of the medium with the first wall structures may however also be stopped so early that remainders of the first wall structures made of the at least one identical material to the first semiconductor layer remain.

Preferably, according to an example embodiment of the present invention, the first wall structures projecting into the at least one first recess are used as support structures for supporting at least the second semiconductor layer for at least one further process performed between the at least partially areally covering of the at least one first recess on the first surface of the first semiconductor layer and the introduction of the medium. Even if the at least one process is traditionally associated with a high risk of deflection or bulging of the second semiconductor layer into the at least one recess, this undesirable occurrence is thus prevented by means of the first wall structures used as support structures.

As an advantageous development of the present invention, at least the following steps can be performed between the at least partially areally covering of the at least one first recess on the first surface of the first semiconductor layer and the introduction of the medium: structuring a multitude of second depressions in the second semiconductor layer starting from a second surface of the second semiconductor layer that faces away from the first semiconductor layer, such that the second depressions form at least one contiguous second recess, comprising a plurality of second depressions, in the second semiconductor layer, into which second wall structures structured out of the second semiconductor layer by means of the second depressions project, and at least partially areally covering the at least one second recess on the second surface of the second semiconductor layer by forming at least one third semiconductor layer from the at least one identical material to the first semiconductor layer, wherein at least one second medium supply opening extending at least through the third semiconductor layer and opening at the assigned second recess is formed for the at least one second recess, wherein the medium is also introduced into the at least one second recess through the at least one second medium supply opening. The introduction of the medium into the at least one second recess may optionally occur simultaneously with the introduction of the medium into the at least one first recess or at an earlier or later time. The layer structure produced by means of the development described here can advantageously be used for the purposes explained below.

Optionally, according to an example embodiment of the present invention, the at least one first medium supply opening and/or the at least one second medium supply opening can be closed such that, at the location of the at least one first recess and/or of the at least one second recess, there is a liquid-tightly and/or gas-tightly sealed cavern in each case. The layer structure produced in this manner can advantageously be used for a variety of devices, e.g., for a sensor device, specifically for a surface micromechanical pressure sensor.

Preferably, according to an example embodiment of the present invention, the at least one first medium supply opening and/or the at least one second medium supply opening results by laser melting the second semiconductor layer and/or the third semiconductor layer. Unlike a deposition method, laser melting allows for the relatively free adjustment of any internal pressure and the inclusion of a freely selectable medium, e.g., a gas or gas mixture, in the at least one liquid-tightly and/or gas-tightly sealed cavern of the produced layer structure.

Alternatively, or additionally, the first wall structures converted at least partially into the product of the chemical reaction due to the chemical reaction with the medium can also be used as support structures for supporting at least the second semiconductor layer for at least one further process performed between the introduction of the medium and the closing of the at least one first medium supply opening. This, too, ensures reliable protection against deflection or bulging, especially during critical processes.

For example, the second semiconductor layer can be formed by growing the second semiconductor layer of monocrystalline or polycrystalline silicon on the first surface of the first semiconductor layer of monocrystalline or polycrystalline silicon. It is however pointed out that feasibility of the method described here is not limited to the use of silicon for at least the first semiconductor layer and the second semiconductor layer.

Furthermore, the devices according to the present invention also realize the advantages explained above.

### BRIEF DESCRIPTION OF THE DRAWINGS

Further features and advantages of the present invention are explained below with reference to the figures.

FIGS. 1Aa, 1Ab, and 1B-1E show cross-sections of (intermediate) products for explaining a first embodiment of the method for forming a layer structure surrounding at least one recess, according to an example embodiment of the present invention.

FIG. 2 shows a cross-section of an (intermediate) product for explaining a second embodiment of the method for forming a layer structure surrounding at least one recess, according to the present invention.

FIG. 3 shows a cross-section of an (intermediate) product for explaining a third embodiment of the method for forming a layer structure surrounding at least one recess, according to the present invention.

FIGS. 4Aa, 4Ab, and 4B show cross-sections of (intermediate) products for explaining a fourth embodiment of the method for forming a layer structure surrounding at least one recess, according to the present invention.

FIGS. 5A and 5B show cross-sections of (intermediate) products for explaining a fifth embodiment of the method for forming a layer structure surrounding at least one recess, according to the present invention.

### DETAILED DESCRIPTION OF EXAMPLE EMBODIMENTS

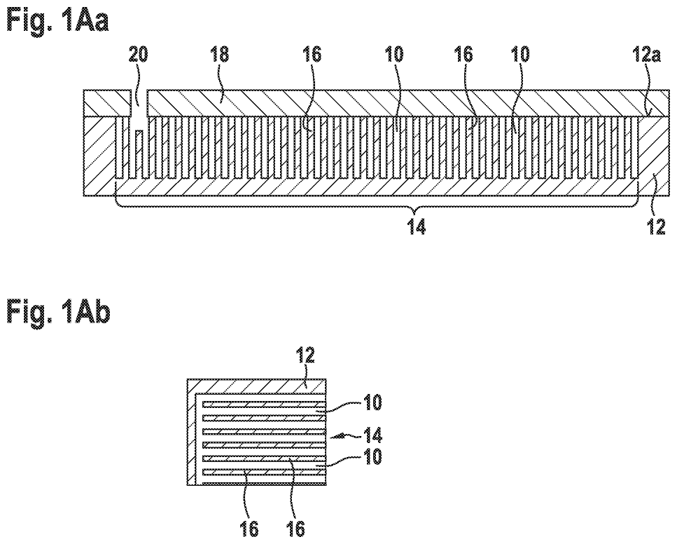

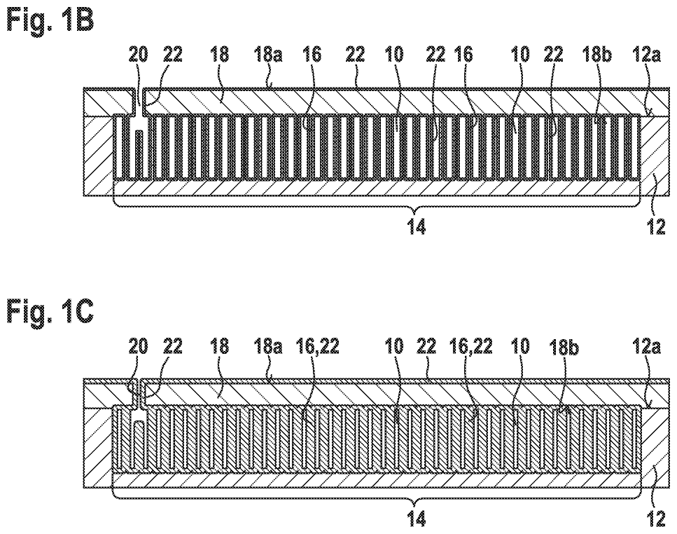

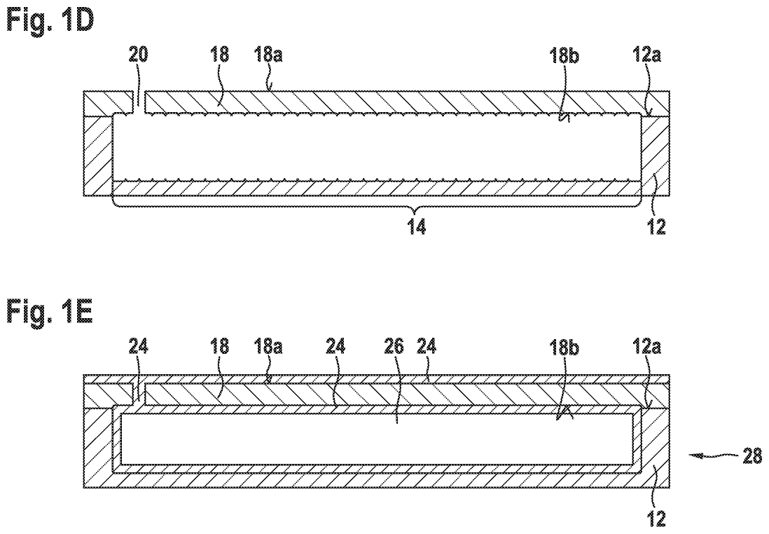

FIGS. 1Aa to 1E show cross-sections of (intermediate) products for explaining a first embodiment of the method for forming a layer structure surrounding at least one recess.

In the embodiment of the method described here, a multitude of (first) depressions 10 is first structured in a first semiconductor layer 12 of the later layer structure. The depressions 10 can also be referred to as trench or channel structures. The structuring of the depressions 10 takes place starting from a first surface 12a of the first semiconductor layer 12. For example, the depressions 10 can be etched into the first semiconductor layer 12 using a photoresist mask and/or a hard mask, specifically of silicon dioxide.

The depressions 10 are formed in the first semiconductor layer 12 such that the depressions 10 form at least one contiguous (first) recess 14, comprising a plurality of depressions 10, in the first semiconductor layer 12. FIG. 1Aa shows a cross-section, perpendicular to the first surface 12a of the first semiconductor layer 12, through the depressions 10, while FIG. 1Ab shows a cross-section, parallel to the first surface 12a, through the depressions 10. As can be seen in FIG. 1Ab, the respective contiguous formation of the at least one recess 14 is in each case to be understood to mean that the depressions 10 comprised by the respective recess 14 “open” into one another (or are interconnected) such that a medium transfer of a liquid or gaseous substance is possible between all the depressions 10 comprised by the same recess 14.

By means of the depressions 10, (first) wall structures 16 are also structured out of the first semiconductor layer 12, which project into the at least one recess 14. The wall structures 16 can also be described as web or pillar structures. The wall structures 16 structured out of the first semiconductor layer 12 are therefore formed from the at least one identical material to the first semiconductor layer 12. The first semiconductor layer 12 is to be understood as a layer comprising at least one semiconductor material as its at least one material. The first semiconductor layer 12 may, for example, be a silicon layer, in particular a monocrystalline silicon layer. It is however pointed out that feasibility of the method described here is not limited to any specific material of the first semiconductor layer 12. Instead of or in addition to silicon, the first semiconductor layer 12 may also comprise at least one further semiconductor material and/or at least one non-semiconductor material, such as at least one electrically insulating material and/or at least one metal.

In a further method step, the at least one recess 14 is at least partially areally covered on the first surface 12a of the first semiconductor layer 12 by forming at least one second semiconductor layer 18 from the at least one identical material to the first semiconductor layer 12. If the second semiconductor layer 18 is arranged directly on the first surface 12a of the first semiconductor layer 12, the second semiconductor layer 18 may be referred to as the closure layer of the at least one recess 14 in the first semiconductor layer 12. The second semiconductor layer 18 is also to be understood as a layer comprising at least one semiconductor material as its at least one material. The second semiconductor layer 18 may, for example, be formed by forming the second semiconductor layer 18 of polycrystalline or epitaxially grown monocrystalline silicon (directly) on the first surface 12a of the first semiconductor layer 12 of (monocrystalline) silicon. Instead of or in addition to silicon, the second semiconductor layer 18 may also comprise at least one further semiconductor material and/or at least one non-semiconductor material, such as at least one electrically insulating material and/or at least one metal.

During or after the formation of the second semiconductor layer 18, at least one (first) medium supply opening 20 extending at least through the second semiconductor layer 18 is formed for the at least one recess 14. The at least one medium supply opening 20 is in each case formed such that each medium supply opening 20 opens at the recess 14 assigned to it and can therefore be used to introduce a gaseous and/or liquid substance into the recess 14 assigned to it. FIG. 1Aa shows the intermediate product after the formation of the second semiconductor layer 18 with the at least one medium supply opening 20 extending through the second semiconductor layer 18. It can be seen that the wall structures 16 structured out of the first semiconductor layer 12 support the second semiconductor layer 18 such that deflection or bulging of the second semiconductor layer 18 is reliably prevented.

FIG. 1B schematically shows the introduction of a medium through the at least one medium supply opening 20 into the at least one recess 14. It is however pointed out here that at least one further process may be performed between the at least partially areally covering of the at least one recess 14 on the first surface 12a of the first semiconductor layer 12 and the introduction of the medium. While performing the at least one further process, the wall structures 16 projecting into the at least one recess 14 serve as support structures for supporting at least the second semiconductor layer 18. Even if the at least one further process would traditionally be associated with a high risk of deflection or bulging of the second semiconductor layer 18, the wall structures 16 thus prevent undesirable deformation of the second semiconductor layer 18. The second semiconductor layer 18 can therefore be easily formed with a comparatively thin layer thickness, without the need to expect undesirable deflection or bulging thereof during the at least one further process. The method described here thus allows for the production of the second semiconductor layer 18 as a warp-free membrane, the deflection or bulging of which is effectively prevented during the process steps.

As shown schematically in FIGS. 1B and 1C, the medium introduced through the at least one medium supply opening 20 into the at least one recess 14 is to be understood as a substance which chemically reacts with the wall structures 16 projecting into the at least one recess 14. Due to the chemical reaction of the medium with the wall structures 16, the wall structures 16 projecting into the at least one recess 14 are thus at least partially converted into a product 22 of the chemical reaction (i.e., into the only product 22 of the chemical reaction or into one of the products 22 of the chemical reaction). The product 22 of the chemical reaction can also be formed on a second surface 18a of the second semiconductor layer 18 that faces away from the first semiconductor layer 12, on a second surface 18b of the second semiconductor layer 18 that faces the first semiconductor layer 12, on the walls of the at least one medium supply opening 20, and/or on the walls of the recess 14. As can be seen in FIG. 1B, by means of the formation of the at least one medium supply opening 20 and by means of the contiguous formation of the at least one recess 14, it is ensured that the medium flows into the at least one recess 14 and around the wall structures 16 projecting thereinto.

The medium carrying out the chemical reaction with the wall structures 16 can be understood to mean a gaseous medium or a liquid medium. When the semiconductor layers 12 and 18 are formed from silicon, oxygen can, for example, be introduced as the medium into the at least one recess 14. By means of the oxygen introduced as the medium, a thermal oxidation process can in this case be caused as the chemical reaction, which leads to the formation of silicon dioxide as the product 22. However, feasibility of the method described here is not limited to the use of oxygen as the medium.

As shown schematically in FIG. 1C, the medium can be introduced into and/or held in the at least one recess 14 until the wall structures 16 projecting into the at least one recess 14 are (almost) fully converted into the product 22 of the chemical reaction due to the chemical reaction of the medium with the wall structures 16. As shown schematically in FIG. 1B, alternatively, the chemical reaction can however also be terminated so early that remainders of the wall structures 16 made of the at least one identical material to the first semiconductor layer 12 still remain.

It can be seen in FIGS. 1B and 1C that the reaction of the medium with at least the wall structures 16 does not lead to clogging of the at least one medium supply opening 20 with the product 22 of the chemical reaction. The pressure prevailing in the at least one recess 14 during the chemical reaction therefore has no influence on a later internal pressure in at least one cavern formed by means of the further method steps at the location of the at least one recess 14.

FIG. 1D shows the intermediate product after removal of the product 22 of the chemical reaction of the medium with the first wall structures 16 from the at least one recess 14. It is however pointed out here that the removal of the product 22 of the chemical reaction from the at least one recess 14 is optional. If desired, the wall structures 16 at least partially converted into the product 22 due to the chemical reaction with the medium can also be retained. If, however, removal of the product 22 of the chemical reaction from the at least one recess 14 is desired, this method step takes place prior to a later closing of the at least one medium supply opening 20. For example, the product 22 of the chemical reaction can be removed selectively to the at least one material of the semiconductor layers 12 and 18 from the at least one recess 14 by means of an etching medium introduced via the at least one medium supply opening 20. Optionally, the removal of the product 22 of the chemical reaction from the at least one recess 14 may, for example, take place by means of an HF gas phase etching process.

A particular advantage of the method described here is that, even if the product 22 of the chemical reaction is later removed from the at least one recess 14, the wall structures 16 at least partially converted into the product 22 of the chemical reaction can still be used as support structures for supporting at least the second semiconductor layer 18 for at least one further process performed between the introduction of the medium and the removal of the product 22 of the chemical reaction with the wall structures 16. In the method described here, the removal of the product 22 of the chemical reaction can be delayed until all critical processes with respect to a deformation of the second semiconductor layer 18 are completed. The method described here can therefore advantageously be integrated into production methods that conventionally comprise problematic processes with respect to a desired flatness or freedom from warping of the second semiconductor layer 18.

FIG. 1E shows the (intermediate) product of the method described here after the closing of the at least one medium supply opening 20. The closing of the at least one medium supply opening 20 is understood to mean at least one particle-tight closing of the at least one medium supply opening 20. Preferably, the at least one medium supply opening 20 is closed in a liquid-tight and/or gas-tight manner in the method step schematically shown in FIG. 1E.

By means of the closing of the at least one medium supply opening 20, a cavern 26 is in each case realized at the location of the at least one recess 14, which cavern is surrounded by a layer structure 28 comprising at least the semiconductor layers 12 and 18. The finished layer structure 28 with its at least one cavern formed as a cavern and/or channel structure 26 can then be used for a variety of devices.

For closing the at least one medium supply opening 20, at least one closure material 24 can, for example, be deposited until the at least one medium supply opening 20 is completely filled with the at least one closure material 24. Deposits of the at least one closure material 24, which, when the at least one closure material 24 is deposited, are often also formed on the second surface 18a of the second semiconductor layer 18, on a second surface 18b of the second semiconductor layer 18 that faces the first semiconductor layer 12, on the walls of the at least one medium supply opening 20, and/or on the walls of the at least one cavern 26, have (substantially) no influence on the later layer structure 28. Merely by way of example, silicon 24 is deposited as the closure material 24 in the embodiment described here.

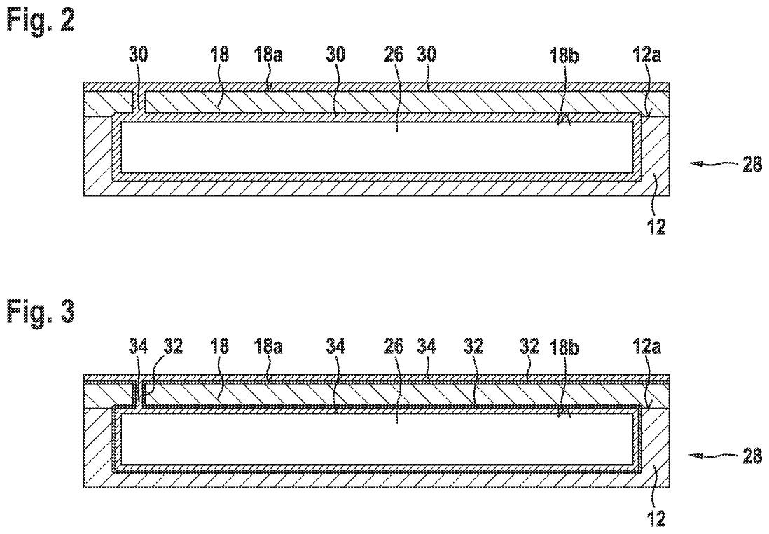

FIG. 2 shows a cross-section of an (intermediate) product for explaining a second embodiment of the method for forming a layer structure surrounding at least one recess.

The embodiment schematically shown in FIG. 2 differs from the above-explained method only in that silicon dioxide 30 is deposited as the closure material 30 for sealing the at least one medium supply opening 20. With respect to further method steps of the method of FIG. 2, reference is made to the embodiment of FIGS. 1Aa to 1E explained above.

FIG. 3 shows a cross-section of an (intermediate) product for explaining a third embodiment of the method for forming a layer structure surrounding at least one recess.

In the embodiment of FIG. 3, a silicon layer 32 is first grown to close the at least one medium supply opening 20. Thereafter, a silicon dioxide layer 34 is deposited until the at least one medium supply opening 20 is completely filled. With respect to further method steps of the method of FIG. 3, reference is made to the embodiment of FIGS. 1Aa to 1E explained above.

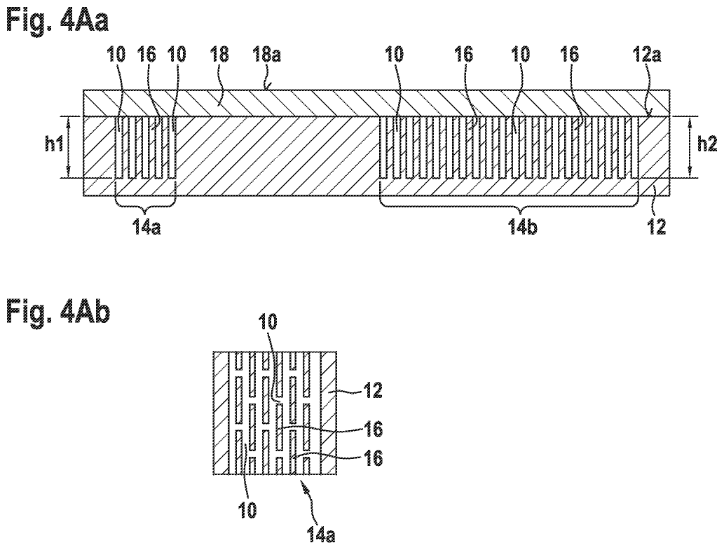

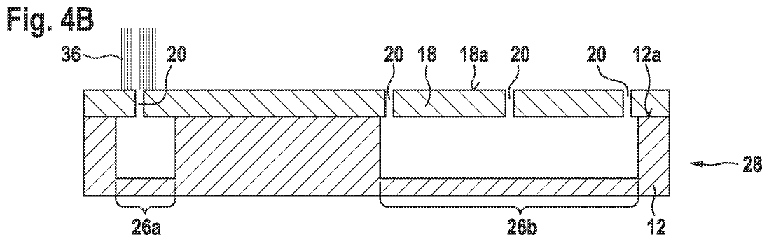

FIGS. 4Aa, 4Ab, and 4B show cross-sections of (intermediate) products for explaining a fourth embodiment of the method for forming a layer structure surrounding at least one recess.

As can be seen in FIG. 4Aa on the basis of a shown cross-section through the depressions 10 in a plane perpendicular to the first surface 12a, a plurality of contiguous recesses 14a and 14b can also be structured in the first semiconductor layer 12 by means of the depressions 10. Optionally, the recesses 14a and 14b may also be connected to one another via at least one channel structure. Although not illustrated, a height h1, perpendicular to the first surface 12a, of the depressions 10 of a first recess 14a may not be equal to a height h2, perpendicular to the first surface 12a, of the depressions 10 of a second recess 14b. The later recesses 14a and 14b (or caverns 26a and 26b) formed by means of the method described here may therefore also have different heights h1 and h2. FIG. 4Ab shows a cross-section, parallel to the first surface 12a of the first semiconductor layer 12, through some of the depressions 10. It can be seen on the basis of a comparison of FIGS. 1Ab and 4Ab that a pattern formed from the depressions 10 of the same recess 14 can be selected with a relatively high freedom of design.

In the method step shown in FIG. 4B, the at least one medium supply opening 20 is closed by laser melting the second semiconductor layer 18. By means of a light beam 36, specifically a laser beam 36 that is directed on the second surface 18a of the second semiconductor layer 18 at the at least one medium supply opening 20, the second semiconductor layer 18 can in each case be locally melted at the location of the at least one medium supply opening 20 such that a later solidification of the melted material leads to closing of the at least one medium supply opening 20. A particular advantage of the method step shown in FIG. 4B is that, during laser melting, the internal pressure in the at least one later cavern 26a and 26b can be selected relatively freely. Furthermore, the closing of the at least one medium supply opening 20 by laser melting can also be used to include a freely selectable gas or gas mixture in the at least one later cavern 26a and 26b.

With respect to further method steps of the method of FIGS. 4Aa, 4Ab, and 4B, reference is made to the embodiments of FIGS. 1Aa to 3 explained above.

All methods explained above can be used to produce a layer structure 28 with a second semiconductor layer 18 designed as a membrane, which delimits the at least one recess 14, 14a and 14b (or cavern 26, 26a and 26b) formed in the layer structure 28. Due to the support/stabilization of the second semiconductor layer 18 during each of the methods by means of the wall structures 16 used as support structures, an advantageous flatness or freedom from warping of the membrane realized therewith is ensured. For example, by means of a chemical-mechanical polishing step performed during one of the methods on the second semiconductor layer 18 supported by means of the wall structures 16, a homogeneous removal for reducing a layer thickness of the second semiconductor layer 18 can be achieved without the processed second semiconductor layer 18 unfavorably deflecting or bulging prior to and/or during the chemical-mechanical polishing step. The second semiconductor layer 18 can therefore also be formed warp-free with a relatively low layer thickness.

A layer structure 28 realized by means of the methods explained above can, for example, be used as at least part of a surface micromechanical pressure sensor, wherein a pressure measurement using the second semiconductor layer 18 used as a pressure-sensitive membrane takes place.

It is however also pointed out that, when performing any of the methods described above, the removal of the wall structures 16 at least partially converted into the product 22 of the chemical reaction due to the chemical reaction with the medium can be dispensed with. Instead, at least remainders of the wall structures 16 can still be retained in the at least one recess 14, 14a and 14b, which remainders can thus still be used to support at least the second semiconductor layer 18 even during operation of a device formed with the layer structure 28. Optionally, at least remainders of the wall structures 16 can also be used to produce thermally insulated regions of the semiconductor layer 18. Via the shaping of the medium supply opening 20, a thermally insulated region consisting of at least a part of the semiconductor layer 18 can possibly also be formed, which region can at least partially be mounted on/fastened to/arranged on non-removed wall structures 16 in the at least one recess 14, 14a and 14b.

The methods described above thus also realize a device as schematically shown in FIGS. 1E, 2, 3 and 4B. The device comprises a layer structure 28 and at least one recess 14, 14a and 14b (or cavern 26, 26a and 26b) formed in a first semiconductor layer 12 of the layer structure 28. The at least one recess 14, 14a and 14b in each case comprises a multitude of first depressions 10 structured in the first semiconductor layer 12 starting from a first surface 12a of the first semiconductor layer 12. In addition, the first depressions 10 form the at least one contiguous first recess 14, 14a and 14b, comprising a plurality of first depressions 10, in the first semiconductor layer 12. The at least one first recess 14, 14a and 14b is in each case at least partially areally covered on the first surface 12a of the first semiconductor layer 12 by means of at least one second semiconductor layer 18 formed from the at least one identical material to the first semiconductor layer 12. Additionally, the layer structure 28 for the at least one first recess 14, 14a and 14b has at least a trace of at least one first medium supply opening 20, which extends at least through the second semiconductor layer 18 and opens at the assigned first recess 14, 14a and 14b. The layer structure 28 also has at least remainders of first wall structures 16 projecting into the at least one first recess 14, 14a and 14b, which wall structures are structured out of the first semiconductor layer 12 by means of the first depressions 10 and are at least partially converted into a product 22 of a chemical reaction of the at least one material of the first semiconductor layer 12 with a medium. Thus, the device described here can be used well for purposes in which supporting at least the second semiconductor layer 18 by means of the remainders of the first wall structures 16 is advantageous.

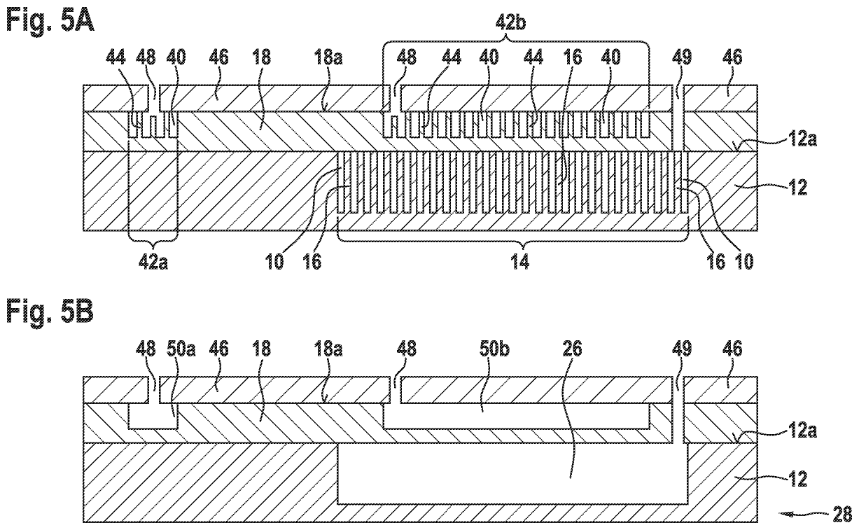

FIGS. 5A and 5B show cross-sections of (intermediate) products for explaining a fifth embodiment of the method for forming a layer structure surrounding at least one recess.

In the method schematically shown in FIGS. 5A and 5B, a multitude of second depressions 40 is first structured in the second semiconductor layer 18 between the at least partially areally covering of the at least one first recess 14, formed in the first semiconductor layer 12, on the first surface 12a and the introduction of the medium. The structuring of the second depressions 40 takes place starting from the second surface 18a of the second semiconductor layer 18 such that the second depressions 40 form at least one contiguous second recess 42a and 42b in the second semiconductor layer 18. In addition, second wall structures 44 are structured out of the second semiconductor layer 18 by means of the second depressions 40 such that the second wall structures 44 project into the at least one second recess 42a and 42b. If at least two second recesses 42a and 42b are formed in the second semiconductor layer 18, they can have different heights perpendicular to the second surface 18a of the second semiconductor layer 18.

As can be seen in FIG. 5A, the at least one second recess 42a and 42b is then at least partially areally covered on the second surface 18a of the second semiconductor layer 18. This takes place by forming at least one third semiconductor layer 46 from the at least one identical material to the first semiconductor layer 12. The third semiconductor layer 46 is also to be understood as a layer comprising at least one semiconductor material as its at least one material. For example, a polycrystalline or epitaxially grown monocrystalline silicon layer can be formed from silicon as the third semiconductor layer 46 directly on the second surface 18a of the second semiconductor layer 18. Instead of or in addition to silicon, the third semiconductor layer 46 may however also comprise at least one further semiconductor material and/or at least one non-semiconductor material, such as at least one electrically insulating material and/or at least one metal.

FIG. 5A shows the intermediate product after the formation of at least one second medium supply opening 48 for the at least one second recess 42a and 42b in the second semiconductor layer 18. The at least one second recess 42a and 42b may optionally be located completely above the at least one first recess 14, at least partially above the at least one first recess 14, or completely outside the region above the at least one first recess 14. The at least one second medium supply opening 48 extending at least through the third semiconductor layer 46 is formed such that it opens in each case at the assigned second recess 42a and 42b. As can be seen in FIG. 5A, the at least one first medium supply opening 20 may also be formed as an opening extending through both the second semiconductor layer 18 and the third semiconductor layer 46. In the embodiment of FIGS. 5A and 5B, the medium supply openings 20 and 48 are also formed such that they can be used to introduce a gaseous and/or liquid substance into the respectively assigned recess 14, 42a and 42b. When introducing (not shown here) the medium into the at least one first recess 14, the medium is also introduced through the at least one second medium supply opening 48 into the at least one second recess 42a and 42b. Instead of simultaneously introducing the medium into the at least one first recess 14 and into the at least one second recess 42a and 42b, the medium may however also be introduced into the at least one first recess 14 prior to or after the introduction of the medium into the at least one second recess 42a and 42b.

If desired, the medium can be retained in the at least one second recess 42a and 42b until the wall structures 44 projecting into the at least one second recess 42a and 42b are (almost) fully converted into the product 22 of the chemical reaction due to the chemical reaction with the medium. Alternatively, however, the chemical reaction may also be stopped prior to the full conversion of the wall structures 44. Optionally, after the completion of the chemical reaction, the product 22 of the chemical reaction may be removed from the at least one second recess 42a and 42b. Alternatively, removal of the product 22 of the chemical reaction from the at least one second recess 42a and 42b may however also be dispensed with.

FIG. 5B shows the intermediate product prior to the closing of the at least one second medium supply opening 48, by means of which a liquid-tightly and/or gas-tightly sealed cavern 50a and 50b is in each case realized at the respective location of the at least one second recess 42a and 42b. The at least one cavern 50a and 50b formed in the second semiconductor layer 18 can be used as a (large-area) cavern region 50b with a reference pressure adjusted therein and/or as a channel structure 50a connected to the cavern region 50b or as a channel structure 50a between two cavern regions. The layer structure 28 shown in FIG. 5B can therefore also advantageously be used for a surface micromechanical pressure sensor.

Optionally, the at least one first medium supply opening 20 may also be closed. It is however pointed out that, even if the at least one second medium supply opening 48 is closed, the at least one first medium supply opening 20 may remain open. By designing the at least one medium supply opening 20 accordingly, the at least one recess 14 formed in the first semiconductor layer 12 can be used to stress-decouple the layer structure/layer composite produced via the at least one recess 14 if closing of the at least one medium supply opening 20 is dispensed with.

By means of the method of FIGS. 5A and 5B, a plurality of planes of recesses 14, 42a and 42b (or caverns/cavities 26 and 50) can thus be realized. It can be seen that the method described here creates a layer structure 28 in which the third semiconductor layer 46 can advantageously be used as a warp-free membrane.

In an alternative embodiment, the wall structures 16 in the at least one first recess 14 can also first be at least partially converted into the product 22 of the chemical reaction of the at least one material of the first semiconductor layer 12 with the medium, before the at least one first medium supply opening 20 is closed by depositing a layer, e.g., silicon dioxide. If desired, the multitude of second depressions 40 can then be structured in the second semiconductor layer 18 such that the second depressions 40 form at least one contiguous second recess 42a and/or 42b in the second semiconductor layer 18. If at least two second recesses 42a and 42b are formed in the second semiconductor layer 18, they can have different heights perpendicular to the second surface 18a of the second semiconductor layer 18. After the subsequent formation of the third semiconductor layer 46, the at least one second medium supply opening 48 is formed such that it extends at least through the third semiconductor layer 46 and opens in the second recess 42a and/or 42b and/or exposes the at least one first medium supply opening 20 in the second semiconductor layer 18. After at least partial conversion of the wall structures 44 in the at least one second recess 42a and 42b into the product 22 of the chemical reaction, the product 22 of the chemical reaction can be removed from the recesses 14, 42a and/or 42b. Alternatively, removal of the product 22 of the chemical reaction may however also be dispensed with. Through the process flow described above, it can be freely selected in which of the recesses 14, 42a, 42b the chemical reaction is initiated by supplying the medium and in which of the recesses 14, 42a, 42b the resulting product 22 is removed. The opening of the medium supply opening 20 and/or 48 and/or the removal of the wall structures 16 and/or 44 may in particular also first take place during the last process steps.

With respect to further method steps of the method of FIGS. 5A and 5B, reference is made to the above-explained embodiments of FIGS. 1Aa to 4B.

The method of FIGS. 5A and 5B thus creates a device with a layer structure 28, at least one first recess 14/cavern 26 formed in a first semiconductor layer 12 of the layer structure 28, which recess/cavern is structured in the first semiconductor layer 12 starting from a first surface 12a of the first semiconductor layer 12 and is at least partially areally covered on the first surface 12a of the first semiconductor layer 12 by means of at least one second semiconductor layer 18 of the layer structure 28, and at least one second recess 42a and 42b/cavern 50a and 50b formed in the second semiconductor layer 18 of the layer structure 28, which recess/cavern extends into the second semiconductor layer 18 starting from a second surface 18a of the second semiconductor layer 18 that faces away from the first semiconductor layer 12. The second semiconductor layer 18 is formed from the at least one identical material to the first semiconductor layer 12. In addition, the at least one second recess 42a and 42b/cavern 50a and 50b formed in the second semiconductor layer 18 is in each case at least partially areally covered on the second surface 18a of the second semiconductor layer 18 by means of at least one third semiconductor layer 46 of the layer structure 28 that is formed from the at least one identical material to the first semiconductor layer 12. For the at least one first recess 14, the layer structure comprises at least a trace of at least one first medium supply opening 20, which extends at least through the second semiconductor layer 18 and the third semiconductor layer 46 and opens at the assigned first recess 14. The at least one first medium supply opening 20 can thus in each case be an open medium supply opening 20 or a closed medium supply opening 20, only the trace of which may still be visible. Accordingly, for the at least one second recess 42a and 42b, at least a trace of at least one second medium supply opening 48, which extends at least through the third semiconductor layer 46 and opens at the assigned second recess 42a and 42b, is also visible on the layer structure 28. The at least one second medium supply opening 48 may also be open or closed, in particular only visible as a trace.

It is again pointed out that all methods explained above can be performed using silicon, such as in particular monocrystalline or polycrystalline silicon, for the at least two semiconductor layers 12, 18 and 46. In this case, thermal oxidation for chemically converting the wall structures 16 and 44 into silicon dioxide can be achieved using oxygen as the medium. It is however again pointed out that the substances mentioned here are to be interpreted only as an example for the feasibility of the methods explained above.

Furthermore, the layer structure 28 shown in the figures can be expanded as desired by further layers/conductive path planes. By re-closing the at least one medium supply opening 48, e.g., by means of a laser, a capacitive or a piezoresistive pressure sensor the cavern 50b of which may have any internal pressure and contain a freely selectable (preferably gaseous) medium can, for example, be produced using the semiconductor layer 46 and the further layers/conductive path planes. By means of the at least one recess 14 in the first semiconductor layer 12 with at least one open medium supply opening 20, the sensitive region of the pressure sensor can be stress-decoupled from the layer system surrounding the pressure sensor.

In a further embodiment, the at least one medium supply opening 20 and/or 48 can also be designed such that it completely surrounds a partial area of the supported semiconductor layer 18 and/or 46. By means of a partial or complete thermal oxidation of the wall structures 16 and/or 44, a more thermally insulated monocrystalline and/or polycrystalline silicon area can thus be created, which can be used, for example, for the production of radiation detectors. An electrical connection of such thermally insulated components can take place by electrically conductive paths extending over the at least one medium supply opening 20 and/or 48.

1-12. (canceled)

13. A method for forming a layer structure surrounding at least one recess, comprising the following steps:
structuring a multitude of first depressions in a first semiconductor layer of the later formed layer structure starting from a first surface of the first semiconductor layer such that a plurality of the first depressions form at least one contiguous first recess in the first semiconductor layer into which first wall structures, structured out of the first semiconductor layer by the first depressions, project;
at least partially areally covering the at least one first recess on the first surface of the first semiconductor layer by forming at least one second semiconductor layer made from at least one identical material as the first semiconductor layer, wherein, for the at least one first recess, at least one first medium supply opening is formed, which extends at least through the second semiconductor layer and opens at the at least one first recess; and
introducing a medium through the at least one first medium supply opening into the at least one first recess, the medium chemically reacting with the projecting first wall structures.

14. The method according to claim 13, wherein a product of the chemical reaction of the medium with the first wall structures is removed from the at least one first recess.

15. The method according to claim 14, wherein the first wall structures converted at least partially into the product of the chemical reaction due to the chemical reaction with the medium are used as support structures for supporting at least the second semiconductor layer for at least one further process performed between the introduction of the medium and the removal of the product of the chemical reaction.

16. The method according to claim 13, wherein the medium is introduced into and/or held in the at least one first recess until the first wall structures projecting into the at least one first recess are fully converted into a product of the chemical reaction due to the chemical reaction of the medium with the first wall structures.

17. The method according to claim 13, wherein the first wall structures projecting into the at least one first recess are used as support structures for supporting at least the second semiconductor layer for at least one further process performed between the at least partially areally covering of the at least one first recess on the first surface of the first semiconductor layer and the introduction of the medium.

18. The method according to claim 13, wherein at least the following steps are performed between the at least partially areally covering of the at least one first recess on the first surface of the first semiconductor layer and the introduction of the medium:
structuring a multitude of second depressions in the second semiconductor layer starting from a second surface of the second semiconductor layer that faces away from the first semiconductor layer, such that a plurality of the second depressions form at least one contiguous second recess in the first semiconductor layer, into which second wall structures, structured out of the second semiconductor layer by the plurality of second depressions, project; and
at least partially areally covering the at least second recess on the second surface of the second semiconductor layer by forming at least one third semiconductor layer from at least one identical material as the first semiconductor layer, wherein, for the at least one second recess, at least one second medium supply opening is formed, which extends at least through the third semiconductor layer and opens at the at least one second recess;
wherein the medium is also introduced through the at least one second medium supply opening into the at least one second recess,

19. The method according to claim 18, wherein the at least one first medium supply opening and/or the at least one second medium supply opening are closed such that, at a location of the at least one first recess and/or of the at least one second recess, there is a liquid-tight and/or gas-tight sealed cavern.

20. The method according to claim 19, wherein the at least one first medium supply opening and/or the at least one second medium supply opening are closed by laser melting the second semiconductor layer and/or the third semiconductor layer.

21. The method according to claim 19, wherein the first wall structures converted at least partially into the product of the chemical reaction due to the chemical reaction with the medium are used as support structures for supporting at least the second semiconductor layer for at least one further process performed between the introduction of the medium and the closing of the at least one first medium supply opening.

22. The method according to claim 14, wherein the second semiconductor layer is formed by growing the second semiconductor layer of monocrystalline or polycrystalline silicon on the first surface of the first semiconductor layer of monocrystalline or polycrystalline silicon.

23. A device, comprising:
a layer structure; and
at least one first continuous recess formed in a first semiconductor layer of the layer structure, the at least one first recess, in each case, includes a multitude of first depressions which are structured in the first semiconductor layer starting from a first surface of the first semiconductor layer, and form the at least one first contiguous recess in the first semiconductor layer from a plurality of the first depressions;
wherein the at least one first continuous recess, is in each case, is at least partially areally covered on the first surface of the first semiconductor layer by at least one second semiconductor layer formed from at least one identical material as the first semiconductor layer;
wherein the layer structure, for the at least one first contiguous recess, includes at least a trace of at least one first medium supply opening, which extends at least through the second semiconductor layer and opens at the assigned first recess, and
and wherein the layer structure includes at least remainders of first wall structures projecting into the at least one first recess, the wall structures, having been structured out of the first semiconductor layer by the plurality of the first depressions, are at least partially converted into a product of a chemical reaction of the at least one material of the first semiconductor layer with a medium.

24. A device, comprising:
a layer structure;
at least one first recess formed in a first semiconductor layer of the layer structure, the at least one first recess having been structured in the first semiconductor layer starting from a first surface of the first semiconductor layer, and each of the least one recess is in each case at least partially areally covered on the first surface of the first semiconductor layer by at least one second semiconductor layer of the layer structure that is formed from at least one identical material as the first semiconductor layer; and
at least one second recess formed in the second semiconductor layer, the ast least one recess having been structured in the second semiconductor layer starting from a second surface of the second semiconductor layer that faces away from the first semiconductor layer, and each of the at least one second recess is in each case at least partially areally covered on the second surface of the second semiconductor layer by at least one third semiconductor layer of the layer structure that is formed from at least one identical material as the first semiconductor layer;
wherein the layer structure, for the at least one first recess, includes at least a trace of at least one first medium supply opening, which extends at least through the second semiconductor layer and the third semiconductor layer and opens at the at least one first recess, and
wherein the layer structure for the at least one second recess, includes at least one structure of at least one second medium supply opening, which extends at least through the third semiconductor layer and opens at the at least one second recess.
